(19) United States
(12) Patent Application Publication
(10) Pub. No.: US 2018/0097500 A1
(43) Pub. Date: Apr. 5, 2018

(54) ELASTIC WAVE DEVICE

(71) Applicant: Murata Manufacturing Co., Ltd., Nagaokakyo-shi (JP)

(72) Inventor: Masakazu MIMURA, Nagaokakyo-shi (JP)

(21) Appl. No.: 15/832,886

(22) Filed: Dec. 6, 2017

Related U.S. Application Data
(63) Continuation of application No. PCT/JP2016/067992, filed on Jun. 16, 2016.

(30) Foreign Application Priority Data
Jul. 6, 2015 (JP) 2015-135584

(51) Int. Cl. H03H 9/02; H03H 9/25; H03H 9/145; H01L 41/047

(52) U.S. Cl. CPC H03H 9/02834; H03H 9/25; H03H 9/145; H03H 9/02559; H03H 9/6483; H03H 9/14541; H03H 9/14544; H01L 41/0477; H03H 9/02637

(57) ABSTRACT

An elastic wave device includes a piezoelectric substrate, an IDT electrode that is provided on the piezoelectric substrate, and a dielectric layer that is provided on the piezoelectric substrate and covers the IDT electrode. The IDT electrode includes a first electrode layer and a second electrode layer that is stacked on the first electrode layer, the first electrode layer including a metal or an alloy with a higher density than a metal included in the second electrode layer and a dielectric included in the dielectric layer. The piezoelectric substrate includes LiNbO₃, and θ of Euler angles (about 0°±5°, θ, about 0°±10°) of the piezoelectric substrate falls within a range of about 8° to about 32°.

### CROSS REFERENCE TO RELATED APPLICATIONS

This application claims the benefit of priority to Japanese Patent Application No. 2015-135584 filed on Jul. 6, 2015 and is a Continuation Application of PCT Application No. PCT/JP2016/067992 filed on Jun. 16, 2016. The entire contents of each application are hereby incorporated herein by reference.

### BACKGROUND OF THE INVENTION

### 1. Field of the Invention

The present invention relates to an elastic wave device that provides a resonator, a high-frequency filter, and the like.

### 2. Description of the Related Art

In the related art, elastic wave devices are widely used as resonators and high-frequency filters.

International Publication No. WO 2005/034347 A1 and Japanese Unexamined Patent Application Publication No. 2013-145930 disclose elastic wave devices in which an IDT electrode is provided on a LiNbO₃ substrate. In International Publication No. WO 2005/034347 A1 and Japanese Unexamined Patent Application Publication No. 2013-145930, a SiO₂ film covers the IDT electrode. It is considered that the frequency-temperature characteristic of the elastic wave device is able to be improved by the SiO₂ film. In addition, in International Publication No. WO 2005/034347 A1, the IDT electrode includes a metal with a higher density than A1. On the other hand, in Japanese Unexamined Patent Application Publication No. 2013-145930, a multilayer metal film, in which an A1 film is stacked on a Pt film, is described as the IDT electrode.

However, in the case where an IDT electrode including single layer structure is provided, as in International Publication No. WO 2005/034347 A1, the electrode finger resistance may increase and loss may increase. On the other hand, an adequate frequency-temperature characteristic may not be obtained with an IDT electrode including a multilayer metal film, as in Japanese Unexamined Patent Application Publication No. 2013-145930. In addition, in the case where a SiO₂ film is provided in order to improve the frequency-temperature characteristic, spurious may be generated by a higher-order mode. Therefore, to date, it has been difficult to obtain an elastic wave device that is able to completely solve the problem of providing low loss, significantly improving a frequency-temperature characteristic and significantly reducing or preventing spurious due to a higher-order mode.

### SUMMARY OF THE INVENTION

Preferred embodiments of the present invention provide elastic wave devices with low loss, with an excellent frequency-temperature characteristic, and in which spurious due to a higher-order mode is unlikely to be generated.

An elastic wave device according to a preferred embodiment of the present invention includes a piezoelectric substrate; an IDT electrode that is provided on the piezoelectric substrate; and a dielectric layer that is provided on the piezoelectric substrate and covers the IDT electrode. The IDT electrode includes a first electrode layer and a second electrode layer that is stacked on the first electrode layer, the first electrode layer including a metal or an alloy with a higher density than a metal included in the second electrode layer and a dielectric included in the dielectric layer. The piezoelectric substrate includes LiNbO₃, and θ of Euler angles (0°±5°, θ, 0°±10°) of the piezoelectric substrate falls within a range of about 8° to about 32°, for example. θ of the Euler angles of the piezoelectric substrate preferably falls, for example, within a range of about 12° to about 26°, and in this case, spurious due to a higher-order mode is able to be further significantly reduced or prevented.

In an elastic wave device according to a preferred embodiment of the present invention, Rayleigh waves are used as a principle mode of elastic waves that propagate along the piezoelectric substrate excited by the IDT electrode, and the first electrode layer includes a thickness at which an acoustic velocity of shear horizontal waves is lower than an acoustic velocity of the Rayleigh waves. In this case, unwanted waves in the vicinity of the passband are able to be significantly reduced or prevented.

In an elastic wave device according to a preferred embodiment of the present invention, the first electrode layer includes at least one selected from a group consisting of Pt, W, Mo, Ta, Au and Cu and alloys of these metals.

In an elastic wave device according to a preferred embodiment of the present invention, the first electrode layer includes Pt or an alloy including Pt as a main component, and the thickness of the first electrode layer is greater than or equal to about 0.047λ, for example.

In an elastic wave device according to a preferred embodiment of the present invention, the first electrode layer includes W or an alloy including W as a main component, and the thickness of the first electrode layer is greater than or equal to about 0.062λ, for example.

In an elastic wave device according to a preferred embodiment of the present invention, the first electrode layer includes Mo or an alloy including Mo as a main component, and the thickness of the first electrode layer is greater than or equal to about 0.144λ, for example.

In an elastic wave device according to a preferred embodiment of the present invention, the first electrode layer includes Ta or an alloy including Ta as a main component, and the thickness of the first electrode layer is greater than or equal to about 0.074λ, for example.

In an elastic wave device according to a preferred embodiment of the present invention, the first electrode layer includes Au or an alloy including Au as a main component, and the thickness of the first electrode layer is greater than or equal to about 0.042λ, for example.

In an elastic wave device according to a preferred embodiment of the present invention, the first electrode layer includes Cu or an alloy including Cu as a main component, and the thickness of the first electrode layer is greater than or equal to about 0.136λ, for example.

In an elastic wave device according to a preferred embodiment of the present invention, the second electrode layer includes Al or an alloy including Al as a main component. In this case, the resistance of the electrode fingers is able to be significantly reduced, and even lower loss is able to be realized.

In an elastic wave device according to a preferred embodiment of the present invention, a thickness of the second electrode layer is greater than or equal to about 0.0175λ, for example. In this case, the resistance of the electrode fingers is able to be significantly reduced, and even lower loss is able to be realized.

In an elastic wave device according to a preferred embodiment of the present invention, the dielectric layer includes at least one dielectric out of SiO₂ and SiN. The dielectric layer preferably includes, for example, SiO₂. In this case, the frequency-temperature characteristic is able to be further significantly improved.

In an elastic wave device according to a preferred embodiment of the present invention, a film thickness of the dielectric layer is greater than or equal to about 0.30λ, for example. In this case, the frequency-temperature characteristic is able to be further significantly improved.

In an elastic wave device according to a preferred embodiment of the present invention, a duty ratio of the IDT electrode is greater than or equal to about 0.48, for example. In this case, spurious due to a higher-order mode is able to be significantly reduced or prevented to a greater degree.

In an elastic wave device according to a preferred embodiment of the present invention, a duty ratio of the IDT electrode is greater than or equal to about 0.55, for example. In this case, spurious due to a higher-order mode is able to be significantly reduced or prevented to a greater degree.

According to the preferred embodiments of the present invention, elastic wave devices with low loss, with an excellent frequency-temperature characteristic, and in which spurious due to a higher-order mode is unlikely to be generated are able to be provided.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1A is a schematic elevational cross-sectional view of an elastic wave device according to a preferred embodiment of the present invention, and FIG. 1B is a plan view illustrating the electrode structure of the elastic wave device.

FIG. 2 is a schematic elevational cross-sectional view in which an electrode portion of the elastic wave device shown in FIGS. 1A and 1B is enlarged.

FIG. 3 is a diagram illustrating the relationship between the film thickness of an Al film and sheet resistance of a multilayer metal film in which an Al film is stacked on a Pt film.

FIG. 4 is a diagram illustrating the relationship between the film thickness of an Al film that is a second electrode layer and the temperature coefficient of frequency (TCF).

FIG. 5 is a diagram illustrating the relationship between the film thickness of a SiO₂ film that is a dielectric layer and the temperature coefficient of frequency (TCF).

FIG. 6A is a diagram illustrating an impedance characteristic and FIG. 6B is a diagram illustrating a phase characteristic when the film thickness of SiO₂ is 0.26λ.

FIG. 7A is a diagram illustrating the impedance characteristic and FIG. 7B is a diagram illustrating the phase characteristic when the film thickness of SiO₂ is 0.30λ.

FIG. 8A is a diagram illustrating the impedance characteristic and FIG. 8B is a diagram illustrating the phase characteristic when the film thickness of SiO₂ is 0.34λ.

FIG. 9A is a diagram illustrating the impedance characteristic and FIG. 9B is a diagram illustrating the phase characteristic when the film thickness of SiO₂ is 0.38λ.

FIG. 10 is a diagram illustrating the relationship between the film thickness of a SiO₂ film and the maximum or substantially maximum phase of a higher-order mode.

FIG. 11A is a diagram illustrating the impedance characteristic and FIG. 11B is a diagram illustrating the phase characteristic when θ=about 24° in Euler angles (0°, θ, 0°).

FIG. 12A is a diagram illustrating the impedance characteristic and FIG. 12B is a diagram illustrating the phase characteristic when θ=about 28° in Euler angles (0°, θ, 0°).

FIG. 13A is a diagram illustrating the impedance characteristic and FIG. 13B is a diagram illustrating the phase characteristic when θ=about 32° in Euler angles (0°, θ, 0°).

FIG. 14A is a diagram illustrating the impedance characteristic and FIG. 14B is a diagram illustrating the phase characteristic when θ=about 36° in Euler angles (0°, θ, 0°).

FIG. 15A is a diagram illustrating the impedance characteristic and FIG. 15B is a diagram illustrating the phase characteristic when θ=about 38° in Euler angles (0°, θ, 0°).

FIG. 16 is a diagram illustrating the relationship between θ and the maximum or substantially maximum phase of a higher-order mode in Euler angles (0°, θ, 0°).

FIGS. 17A to 17C are diagrams respectively illustrating the relationship between θ of Euler angles (0°, θ, 0°) and the bandwidth ratio of shear horizontal waves when the film thickness of a Pt film is 0.015λ, 0.025λ, or 0.035λ.

FIGS. 18A to 18C are diagrams respectively illustrating the relationship between θ of Euler angles (0°, θ, 0°) and the bandwidth ratio of shear horizontal waves when the film thickness of a Pt film is 0.055λ, 0.065λ, or 0.075λ.

FIG. 19 is a diagram illustrating the relationships between the film thickness of a Pt film and the acoustic velocities of Rayleigh waves and shear horizontal waves.

FIG. 20A is a diagram illustrating the impedance characteristic and FIG. 20B is a diagram illustrating a phase characteristic of an elastic wave device manufactured in an experimental example.

FIG. 21 is a diagram illustrating the relationships between the film thickness of a W film and the acoustic velocities of Rayleigh waves and shear horizontal waves.

FIG. 22 is a diagram illustrating the relationships between the film thickness of a Mo film and the acoustic velocities of Rayleigh waves and shear horizontal waves.

FIG. 23 is a diagram illustrating the relationships between the film thickness of a Ta film and the acoustic velocities of Rayleigh waves and shear horizontal waves.

FIG. 24 is a diagram illustrating the relationships between the film thickness of an Au film and the acoustic velocities of Rayleigh waves and shear horizontal waves.

FIG. 25 is a diagram illustrating the relationships between the film thickness of a Cu film and the acoustic velocities of Rayleigh waves and shear horizontal waves.

FIG. 26A is a diagram illustrating the impedance characteristic and FIG. 26B is a diagram illustrating the phase characteristic when the duty ratio is 0.50.

FIG. 27A is a diagram illustrating the impedance characteristic and FIG. 27B is a diagram illustrating the phase characteristic when the duty ratio is 0.60.

FIG. 28A is a diagram illustrating the impedance characteristic and FIG. 28B is a diagram illustrating the phase characteristic when the duty ratio is 0.70.

FIG. 29 is a diagram illustrating the relationship between the duty ratio of an IDT electrode and the maximum phase of a higher-order mode.

### DETAILED DESCRIPTION OF THE PREFERRED EMBODIMENTS

Hereafter, the present invention will be made clearer by describing specific preferred embodiments of the present invention while referring to the drawings.

The preferred embodiments described in the present specification are illustrative examples and it should be noted that portions of the configurations illustrated in different preferred embodiments are able to be substituted for one another or combined with one another.

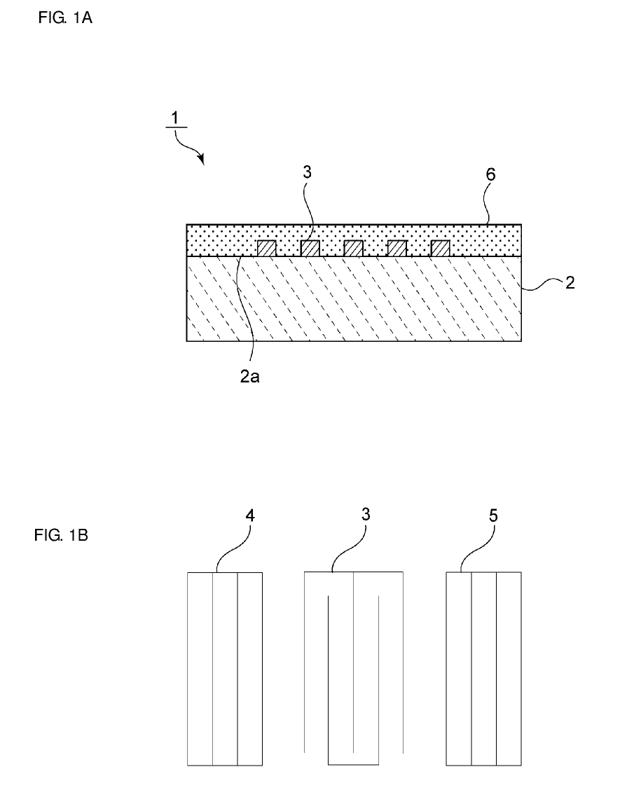

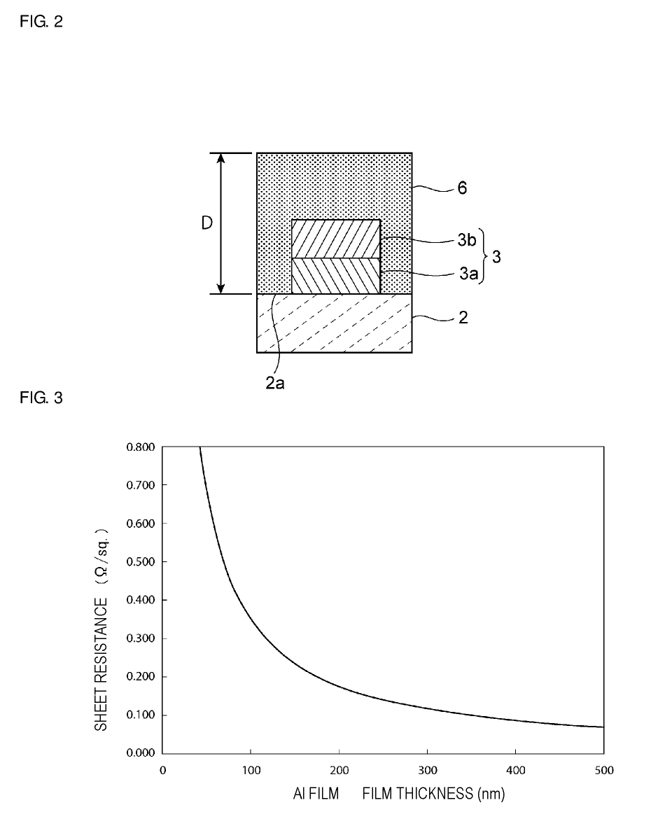

FIG. 1A is a schematic elevational cross-sectional view of an elastic wave device according to a preferred embodiment of the present invention, and FIG. 1B is a plan view illustrating the electrode structure of the elastic wave device. FIG. 2 is a schematic elevational cross-sectional view in which an electrode portion of the elastic wave device shown in FIGS. 1A and 1B is enlarged.

An elastic wave device 1 includes a piezoelectric substrate 2. The piezoelectric substrate 2 includes a main surface 2a. The piezoelectric substrate 2 includes LiNbO₃. In Euler angles (0°±5°, θ, 0°±10°) of the piezoelectric substrate 2, 0 is within a range of about 8° to about 32°, for example. Therefore, the elastic wave device 1 is able to significantly reduce or prevent generation of spurious due to a higher-order mode.

θ is preferably less than or equal to about 30°, more preferably less than or equal to about 28°, and even more preferably greater than or equal to about 12° and less than or equal to about 26°, for example. In this case, generation of spurious due to a higher-order mode is able to be significantly reduced or prevented to a greater degree.

An IDT electrode 3 is provided on the main surface 2a of the piezoelectric substrate 2. As a principle mode, Rayleigh waves are elastic waves excited by the IDT electrode 3 in the elastic wave device 1. In the present specification, as illustrated in FIG. 1B, λ represents the wavelength of a surface acoustic wave that is a fundamental wave of a longitudinal mode determined by the pitch of the electrode fingers of the IDT electrode 3.

More specifically, the electrode structure illustrated in FIG. 1B is provided on the piezoelectric substrate 2. That is, the IDT electrode 3 and reflectors 4 and 5 are formed, the reflectors 4 and 5 being located on both sides of the IDT electrode 3 in the propagation direction of an elastic wave. Thus, a one-port elastic wave resonator is provided. However, an electrode structure including an IDT electrode is not especially limited. A filter may be provided by combining a plurality of resonators. Examples of such a filter include a ladder filter, a longitudinally coupled resonator filter, a lattice filter, and so on.

The IDT electrode 3 includes first and second busbars, and a plurality of first and second electrode fingers. The plurality of first and second electrode fingers extend in a direction that is perpendicular or substantially perpendicular to the elastic wave propagation direction. The plurality of first electrode fingers and the plurality of second electrode fingers are interposed between one another. In addition, the plurality of first electrode fingers are connected to the first busbar, and the plurality of second electrode fingers are connected to the second busbar.

As illustrated in FIG. 2, the IDT electrode 3 includes first and second electrode layers 3a and 3b. The second electrode layer 3b is stacked on the first electrode layer 3a. The first electrode layer 3a includes a metal or an alloy with a higher density than a metal included in the second electrode layer 3b and a dielectric included in a dielectric layer 6.

The first electrode layer 3a includes a metal, for example, Pt, W, Mo, Ta, Au, and Cu, or an alloy of such a metal. The first electrode layer 3a preferably includes Pt or an alloy including Pt as a main component, for example.

The second electrode layer 3b preferably includes Al or an alloy including Al as a main component. Preferably, for example, the second electrode layer 3b includes a metal or an alloy with a lower resistivity than the first electrode layer 3a from the viewpoint of making the resistance of the electrode fingers small and further significantly reducing or preventing loss. Therefore, the second electrode layer 3b preferably includes Al or an alloy including Al as a main component, for example. In the present specification, “main component” refers to a component that is at least about 50 wt %. The film thickness of the second electrode layer 3b is preferably greater than or equal to about 0.0175λ from the viewpoint of making the resistance of the electrode fingers small and further significantly reducing or preventing loss, for example. In addition, the film thickness of the second electrode layer 3b is preferably less than or equal to about 0.2λ, for example.

The IDT electrode 3 may be a multilayer metal film in which another metal is stacked in addition to the first and second electrode layers 3a and 3b. The other metal is not particularly limited, and may be a metal or an alloy, for example, Ti, NiCr, or Cr.

Preferably, for example, a metal film including Ti, NiCr, Cr or the like is an adhesive film that increases the bonding strength between the first electrode layer 3a and the second electrode layer 3b.

The dielectric layer 6 is provided on the main surface 2a of the piezoelectric substrate 2 and covers the IDT electrode 3. The material included in the dielectric layer 6 is not particularly limited. A suitable material, for example, silicon oxide, silicon nitride, silicon oxynitride, aluminum nitride, tantalum oxide, titanium oxide, or alumina is included as the material of the dielectric layer 6. Preferably, for example, at least one out of SiO₂ and SiN be included as the material of the dielectric layer 6 from the viewpoint of further significantly improving the frequency-temperature characteristic. Preferably, SiO₂ is included, for example.

The film thickness of the dielectric layer 6 is preferably greater than or equal to about 0.30λ from the viewpoint of further significantly improving the frequency-temperature characteristic, for example. In addition, the film thickness of the dielectric layer 6 is preferably less than or equal to about 0.50λ, for example.

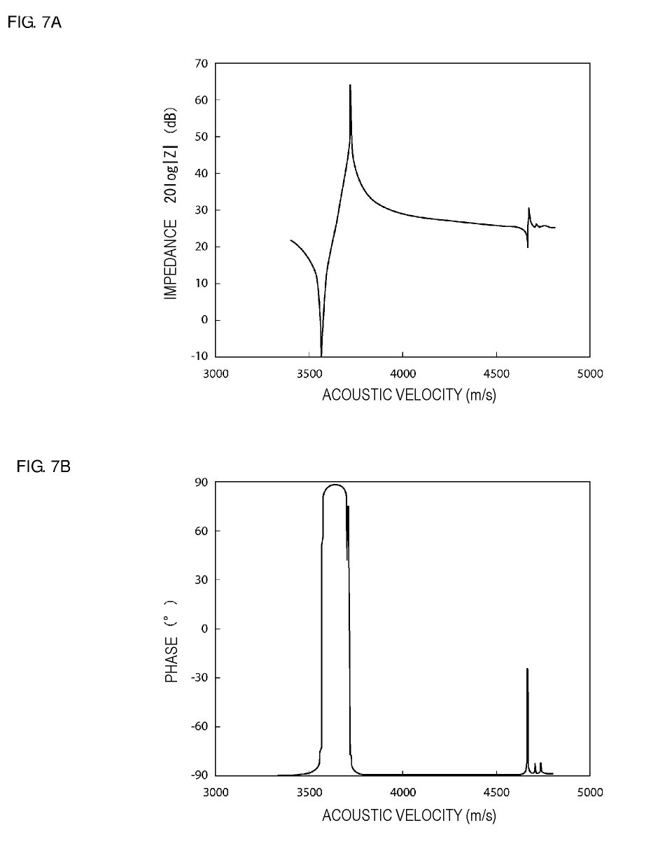

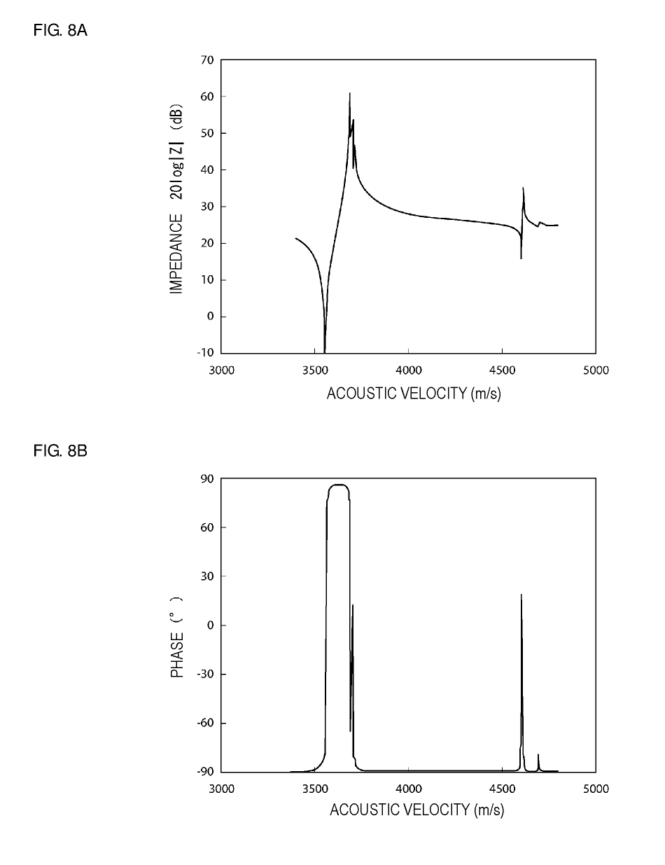

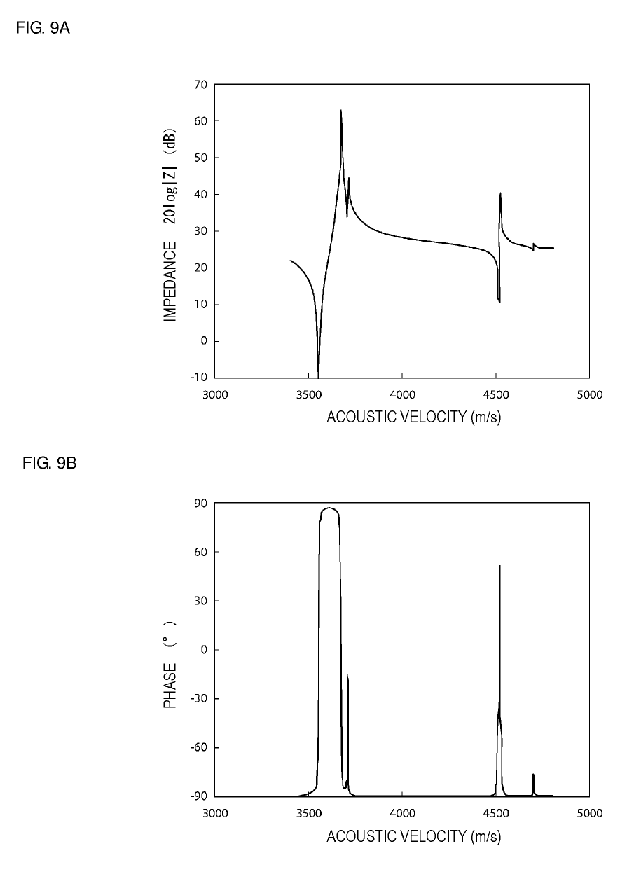

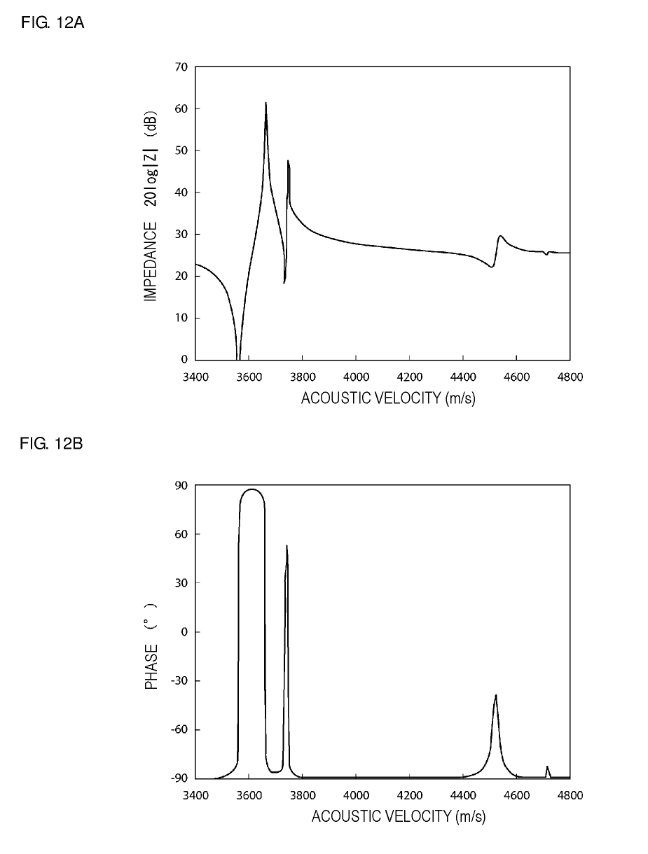

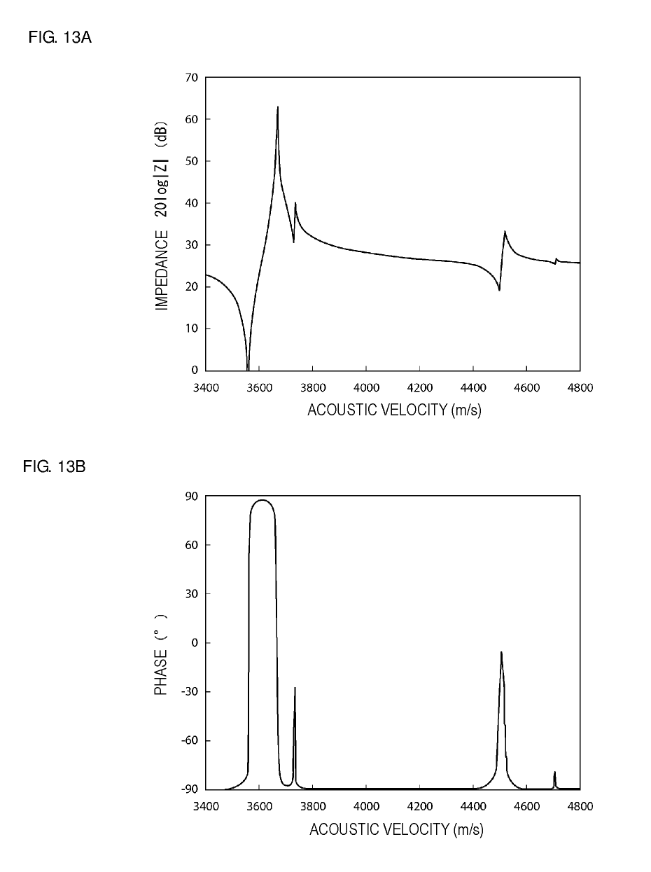

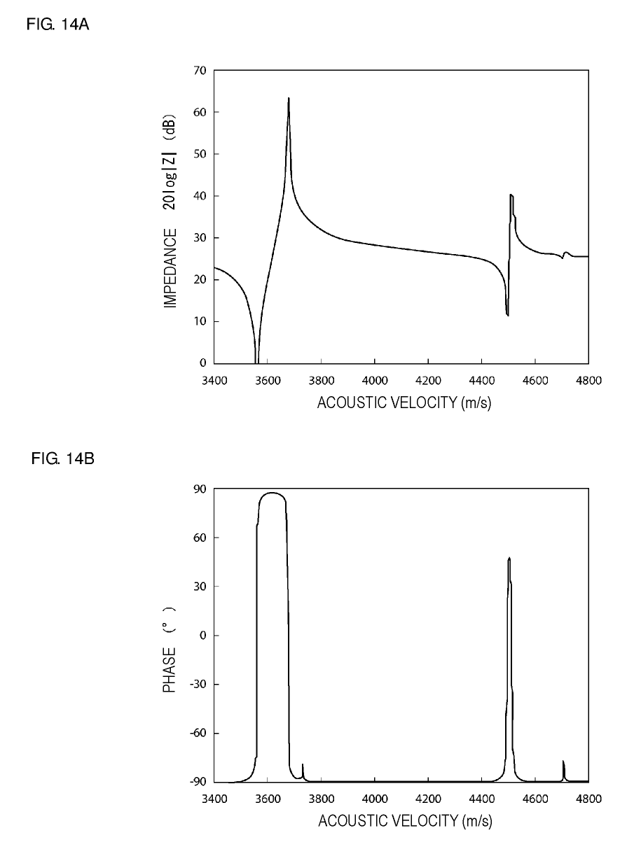

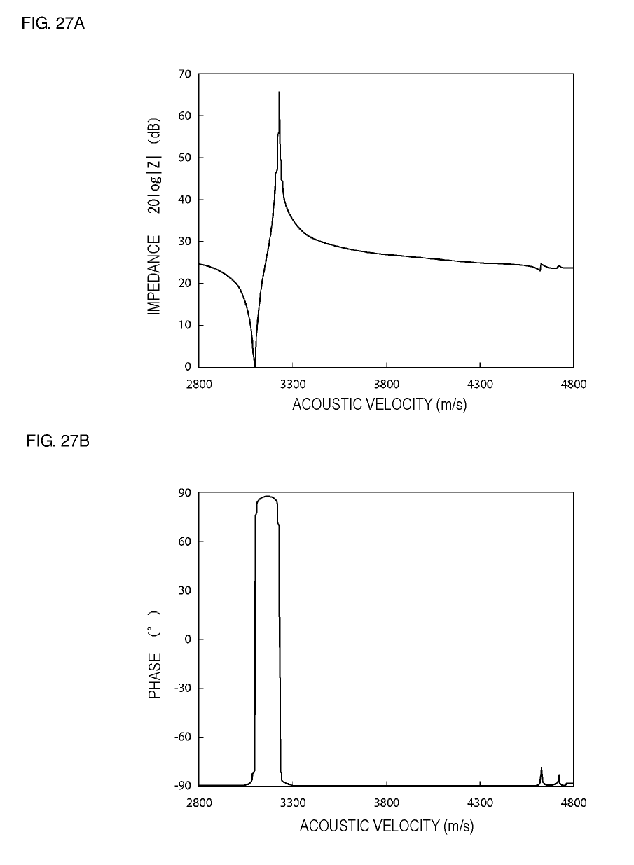

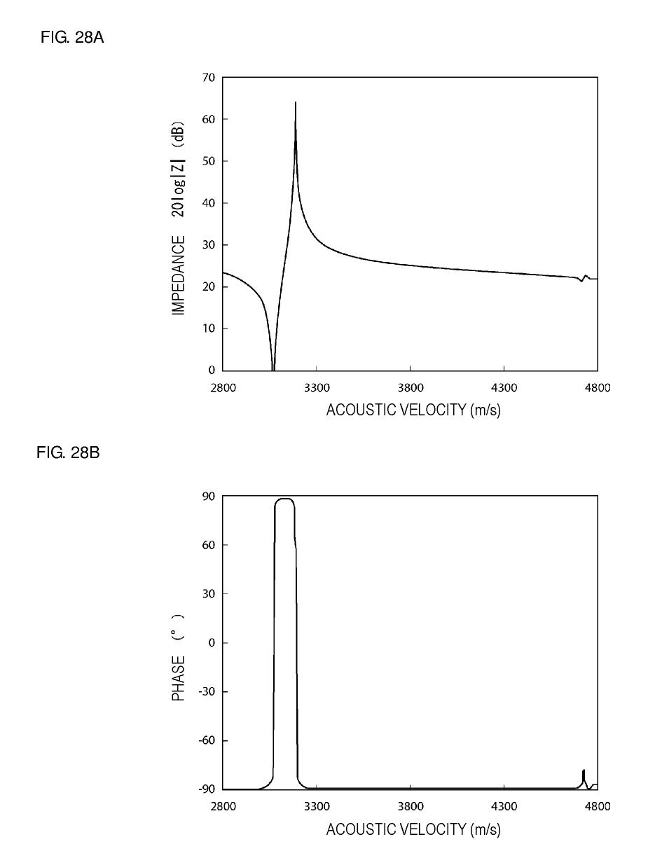

In the elastic wave device 1, the piezoelectric substrate 2 includes LiNbO₃ and θ of the Euler angles (0°±5°, θ, 0°±10°) of the piezoelectric substrate 2 is in the range of about 8° to about 32°, as described above, for example. In addition, the IDT electrode 3 includes a multilayer metal film in which the high-density first electrode layer 3a defines and functions as the lower layer. In addition, the dielectric layer 6 covers the IDT electrode 3. Therefore, an elastic wave device is able to be provided with low loss, with an excellent frequency-temperature characteristic, and in which spurious due to a higher-order mode is unlikely to be generated. This point will be described in more detail hereafter while referring to FIGS. 3 to 29.

FIG. 3 is a diagram illustrating the relationship between the film thickness of an Al film and sheet resistance of a multilayer metal film in which an Al film is stacked on a Pt film. It is clear from FIG. 3 that the sheet resistance becomes smaller as the film thickness of the Al film increases. The sheet resistance was 0.5 (Ω/sq.) when the film thickness of the Al film was about 70 nm (0.035λ in case where λ=about 2.0 μm, 0.0175λ in case where λ=about 4.0 μm), and the sheet resistance was 0.2 (Ω/sq.) when the film thickness of the Al film was about 175 nm (0.0875λ in case where Xλ=about 2.0 μm, 0.04375λ in case where λ=about 4.0 μm), for example. In addition, the sheet resistance was 0.1 (Ω/sq.) when the film thickness of the Al film was about 350 nm (0.175λ in case where λ=about 2.0 μm, 0.0875λ in case where λ=about 4.0 μm), for example.

In the case where this multilayer metal film is included in a device, for example, the elastic wave device 1, it is preferable that the sheet resistance is sufficiently small from the viewpoint of reducing loss in the device. Specifically, the sheet resistance is preferably less than or equal to about 0.5 (Ω/sq.), more preferably less than or equal to about 0.2 (Ω/sq.), and still more preferably less than or equal to about 0.1 (Ω/sq.), for example. Therefore, the film thickness of the Al film in the multilayer metal film is preferably greater than or equal to about 70 nm, more preferably greater than or equal to about 175 nm, and still more preferably greater than or equal to about 350 nm, for example. In addition, the film thickness of the Al film in the multilayer metal film is preferably less than or equal to about 0.2λ, for example, from the viewpoint of significantly reducing or preventing degradation of the frequency-temperature characteristic, which is described later.

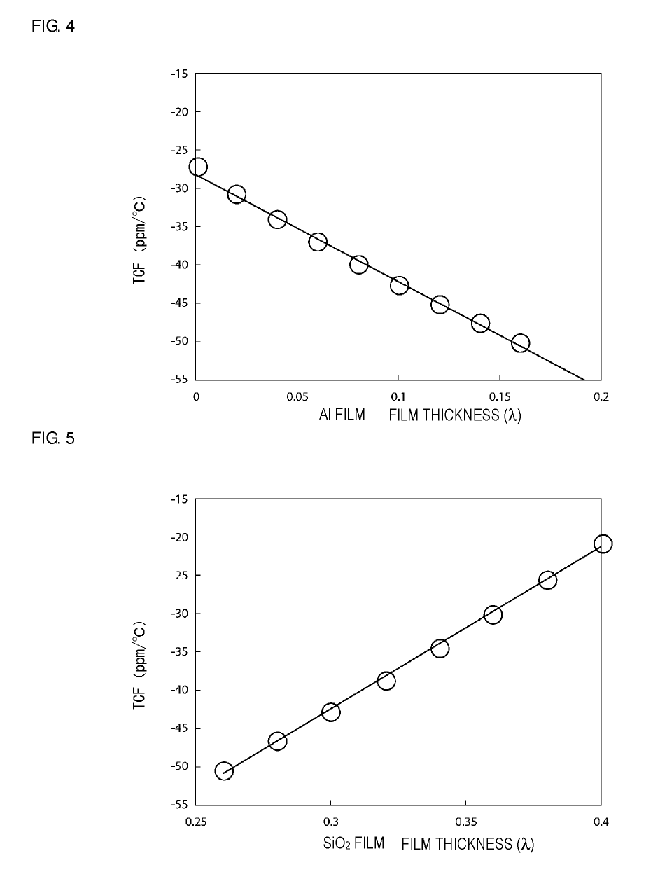

FIG. 4 is a diagram illustrating the relationship between the film thickness of the Al film that is the second electrode layer and the temperature coefficient of frequency (TCF). FIG. 4 illustrates results that were obtained when an elastic wave resonator designed as stipulated below was provided with the structure illustrated in FIGS. 1 and 2.

Piezoelectric substrate 2 . . . LiNbO₃ substrate, Euler angles (0°, about 38°, 0°)

First electrode layer 3a . . . Pt film, film thickness: about 0.02λ

Second electrode layer 3b . . . Al film,

IDT electrode 3 . . . duty ratio: about 0.50

Dielectric layer 6 . . . SiO₂ film, film thickness D: about 0.3λ

Elastic waves . . . principle mode: Rayleigh waves

It is clear from FIG. 4 that TCF deteriorates as the film thickness of the Al film becomes larger. Specifically, the amounts of deterioration in TCF (ΔTCF) with respect to the film thickness of the Al film when the wavelength λ is about 2.0 μm (corresponding to a frequency of about 1.8 GHz) are listed in below Table 1. In addition, the amounts of deterioration in TCF (ΔTCF) with respect to the film thickness of the Al film when the wavelength X is about 4.0 μm (corresponding to a frequency of about 900 MHz) are listed in below Table 2.

FIG. 5 is a diagram illustrating the relationship between the film thickness of a silicon oxide (SiO2) film that is dielectric layer and the temperature coefficient of frequency (TCF). FIG. 5 illustrates results that were obtained when an elastic wave resonator designed as stipulated below was provided with the structure illustrated in FIGS. 1 and 2.

Piezoelectric substrate 2 . . . LiNbO₃ substrate, Euler angles (0°, about 38°, 0°)

First electrode layer 3a . . . Pt film, film thickness: about 0.02λ

Second electrode layer 3b . . . Al film, film thickness: about 0.10λ

IDT electrode 3 . . . duty ratio: about 0.50

Dielectric layer 6 . . . SiO₂ film

Elastic waves . . . principle mode: Rayleigh waves

As illustrated in FIG. 5, it is clear that TCF significantly improves as the film thickness D of the SiO2 film becomes larger. From this relationship, the increases in the film thickness D of the SiO2 film (ΔSiO₂) that compensate for the amounts of degradation TCF that occur with the addition of the Al film were obtained. The results are listed in Tables 1 and 2 below. Table 1 illustrates the results for the case where λ=about 2.0 μm (corresponding to a frequency of about 1.8 GHz), and Table 2 illustrates the results for the case where λ=about 4.0 μm (corresponding to a frequency of about 900 GHz).

TABLE 1

| | | Film | | |
|---|---|---|---|---|
| | Film | Thickness | | |
| Sheet | Thickness | of Al Film | | ΔSiO₂ |
| Resistance | of Al Film | (Wavelength | ΔTCF | (Wavelength |
| (Ω/sq.) | [nm] | Ratio) [λ] | [ppm/° C.] | Ratio) [λ] |
| | 0 | 0 | 0 | 0 |
| 0.5 | 70 | 0.035 | −5 | 0.023 |
| 0.2 | 175 | 0.0875 | −12.5 | 0.058 |
| 0.1 | 350 | 0.175 | −25 | 0.117 |

TABLE 2

| | | Film | | |
|---|---|---|---|---|
| | Film | Thickness | | |
| Sheet | Thickness | of Al Film | | ΔSiO₂ |
| Resistance | of Al Film | (Wavelength | ΔTCF | (Wavelength |
| (Ω/sq.) | [nm] | Ratio) [λ] | [ppm/° C.] | Ratio) [λ] |
| | 0 | 0 | 0 | 0 |
| 0.5 | 70 | 0.0175 | −2.5 | 0.012 |
| 0.2 | 175 | 0.04375 | −6.25 | 0.029 |
| 0.1 | 350 | 0.0875 | −12.5 | 0.058 |

Therefore, in the case where an Al film is provided in order to significantly improve sheet resistance, TCF degradation of between about 10 to about 20 ppm/° C. is incurred in order to obtain a sufficient sheet resistance value.

In order to compensate for this degradation of TCF, it is preferable to increase the film thickness D of the SiO₂ film by 0.05λ to about 0.10λ in the wavelength ratio, for example.

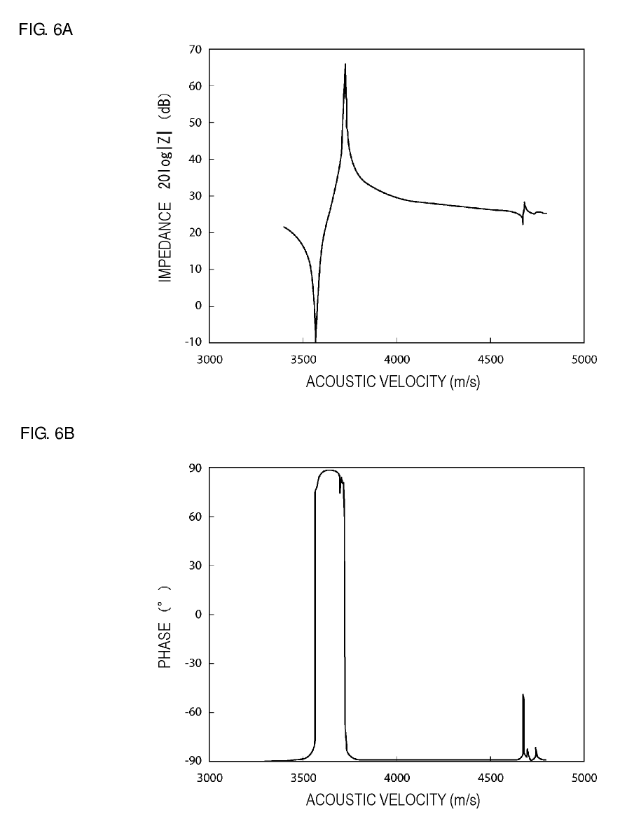

In each of FIGS. 6 to 9, part (a) is a diagram illustrating the magnitude of impedance and part (b) is a diagram illustrating the phase characteristic when the acoustic velocity, which is expressed as the product of the frequency and the wavelength, is changed, the film thickness of the SiO₂ film being changed from figure to figure. In FIGS. 6 to 9, values of film thickness of the SiO2 film obtained by normalizing the film thickness D of the SiO₂ film by the wavelength are 0.26λ, 0.30λ, 0.34λ, and 0.38λ in this order. In addition, FIGS. 6 to 9 illustrate results that were obtained when an elastic wave resonator designed as stipulated below was provided with the structure illustrated in FIGS. 1 and 2.

Piezoelectric substrate 2 . . . LiNbO₃ substrate, Euler angles (0°, about 38°, 0°)

First electrode layer 3a . . . Pt film, film thickness: about 0.02λ

Second electrode layer 3b . . . Al film, film thickness: about 0.10λ

IDT electrode 3 . . . duty ratio: about 0.50

Dielectric layer 6 . . . SiO₂ film

Elastic waves . . . principle mode: Rayleigh waves

It is clear from FIGS. 6 to 9 that spurious of a higher-order mode located in the vicinity of an acoustic velocity of about 4700 m/s becomes larger as the film thickness of the SiO₂ film increases. It is preferable to make the maximum or substantially maximum phase of the higher-order mode be less than or equal to about −25° in order to significantly reduce or prevent degradation of characteristics of the entire device due to the effect of the higher-order mode.

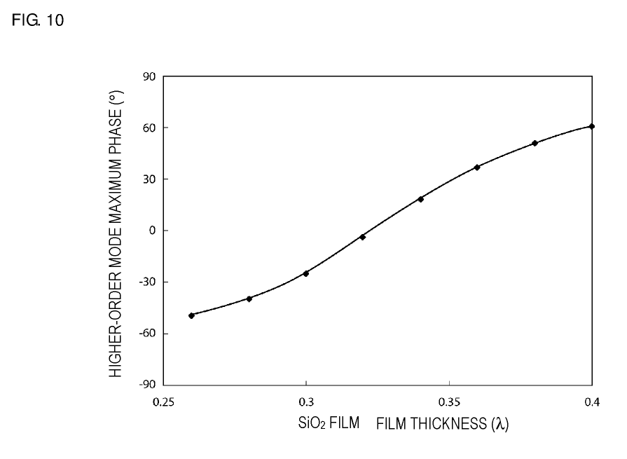

FIG. 10 is a diagram illustrating the relationship between the film thickness of the SiO₂ film and the maximum or substantially maximum phase of the higher-order mode. FIG. 10 illustrates results obtained when an elastic wave resonator with a same or similar design as that included in the case illustrated in FIGS. 6 to 9 was provided.

As illustrated in FIG. 10, it is clear that the maximum or substantially maximum phase of the higher-order mode is larger than about −25° when the SiO₂ film thickness is made to be greater than or equal to about 0.30λ, for example. Accordingly, the higher-order mode becomes large and an outside-of-passband characteristic is degraded when the SiO₂ film is made to be 0.30λ or higher in order to compensate for degradation of TCF due to the addition of the Al film. Therefore, in the related art, it has not been possible to obtain an elastic wave resonator that provides low loss, significant improvement of TCF, and a satisfactory outside-of-passband characteristic.

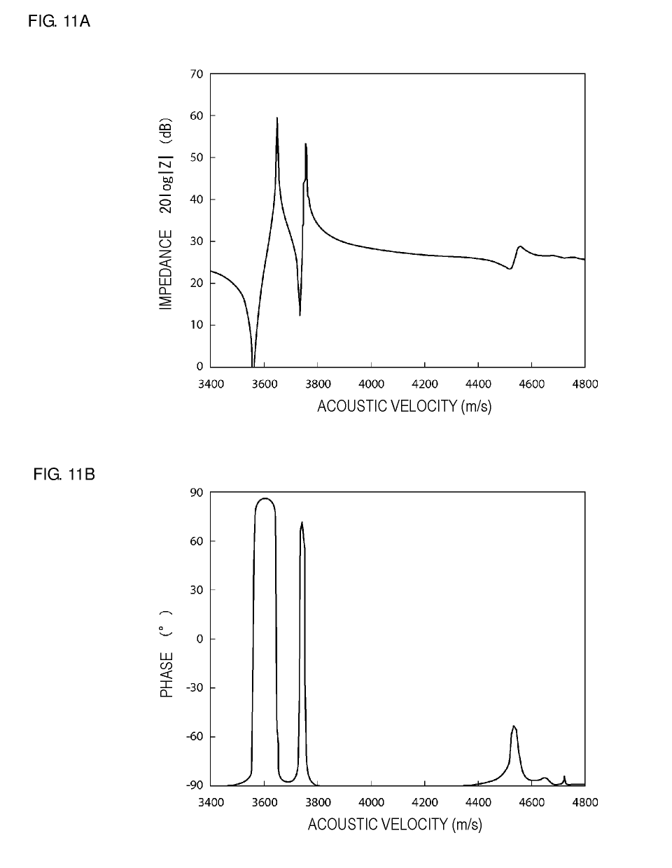

In FIGS. 11 to 15, parts (a) are diagrams illustrating the impedance characteristic and parts (b) are diagrams illustrating the phase characteristic when θ of the Euler angles (0°, θ,0°) of a piezoelectric substrate is changed. In FIGS. 11 to 15, θis respectively set to about 24°, about 28°, about 32°, about 36°, and about 38° in this order, for example. In addition, FIGS. 11 to 15 illustrate results that were obtained when an elastic wave resonator designed as stipulated below was provided in the structure illustrated in FIGS. 1 and 2. The illustrated film thicknesses of the electrode layers and the dielectric layer were normalized by the wavelength λ.

Piezoelectric substrate 2 . . . LiNbO₃ substrate, Euler angles (0°, θ, 0°)

First electrode layer 3a . . . Pt film, film thickness: about 0.02λ

Second electrode layer 3b . . . Al film, film thickness: about 0.10λ

IDT electrode 3 . . . duty ratio: about 0.50

Dielectric layer 6 . . . SiO₂ film, film thickness D: about 0.40λ

Elastic waves . . . principle mode: Rayleigh waves

It is clear from FIGS. 11 to 15 that the higher-order mode spurious becomes smaller as θ is decreased.

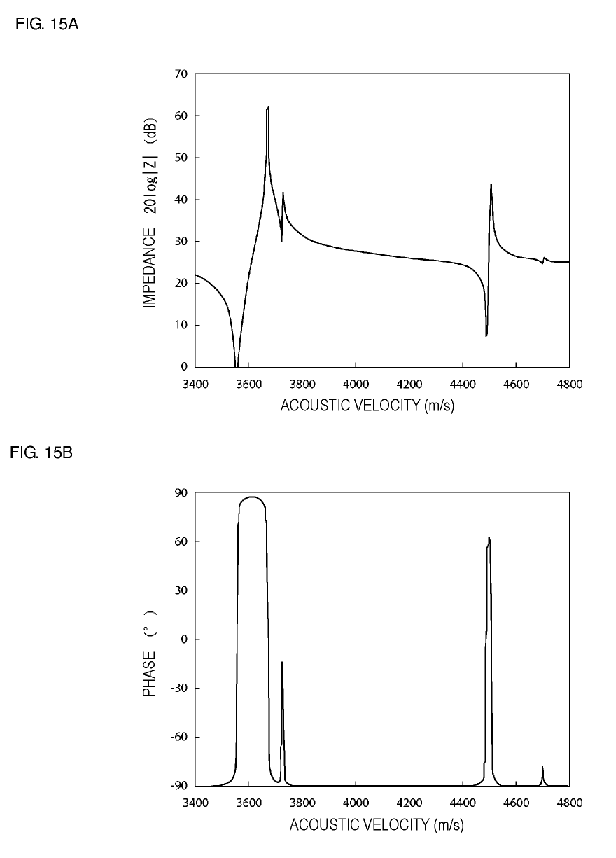

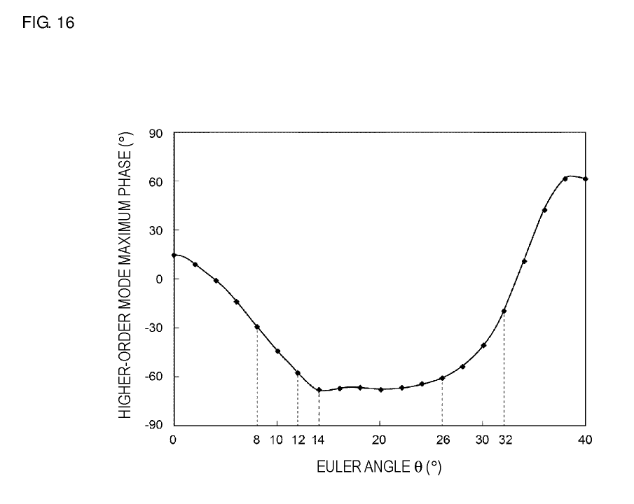

In addition, FIG. 16 is a diagram illustrating the relationship between θ of Euler angles (0°, θ, 0°) and the maximum or substantially maximum phase of the higher-order mode. FIG. 16 illustrates results obtained when an elastic wave resonator with a same or similar design as that included in the case illustrated in FIGS. 11 to 15 was provided. It is clear from FIG. 16 that the maximum or substantially maximum phase of the higher-order mode is less than or equal to about −25° when θ is greater than or equal to about 8° and less than or equal to about 32°, for example. In other words, it is clear that the generation of spurious of a higher-order mode is able to be sufficiently significantly reduced or prevented when θ is greater than or equal to about 8° and less than or equal to about 32° and the film thickness of the SiO₂ film is about 0.40λ, for example. θ of the Euler angles is preferably, for example, greater than or equal to about 12° and less than or equal to about 26°, and spurious of the higher-order mode is able to be significantly reduced or prevented to an even greater extent in this case.

Thus, the inventors of the present application discovered that an elastic wave resonator is able to achieve low loss, significant improvement of TCF and a satisfactory outside-of-passband characteristic by making θ of the Euler angles (0°, θ, 0°) greater than or equal to about 8° and less than or equal to about 32°, for example, in addition to adopting the above-described features and elements.

However, it is clear from FIGS. 11 to 15 that large spurious is generated in the vicinity of the main resonance (acoustic velocity of about 3700 m/s) as θ is made smaller. This spurious is due to shear horizontal waves, which are unwanted waves, being excited in addition to the Rayleigh waves, which are used as the principle mode. This spurious is able to be significantly reduced or prevented by significantly reducing the electromechanical coupling coefficient of the shear horizontal waves.

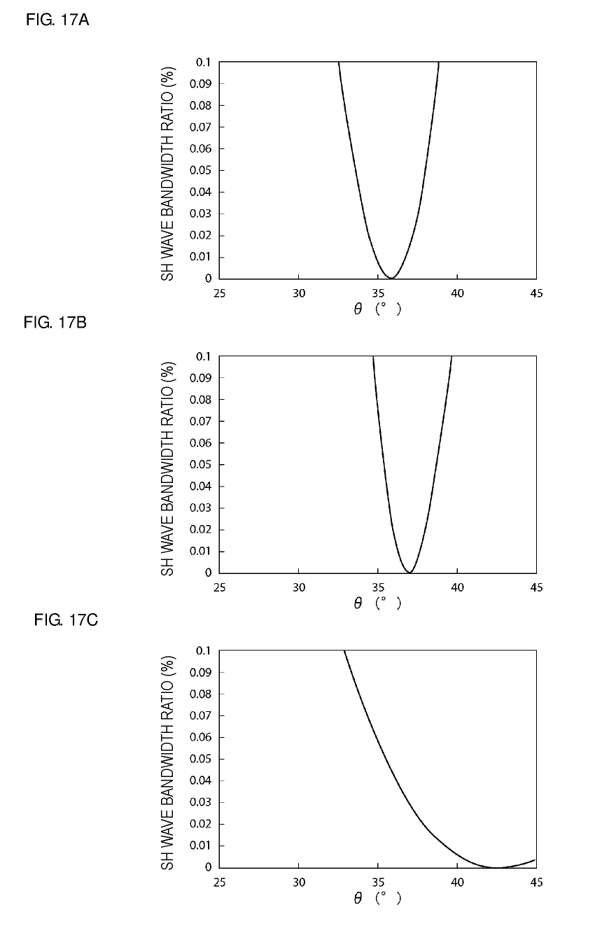

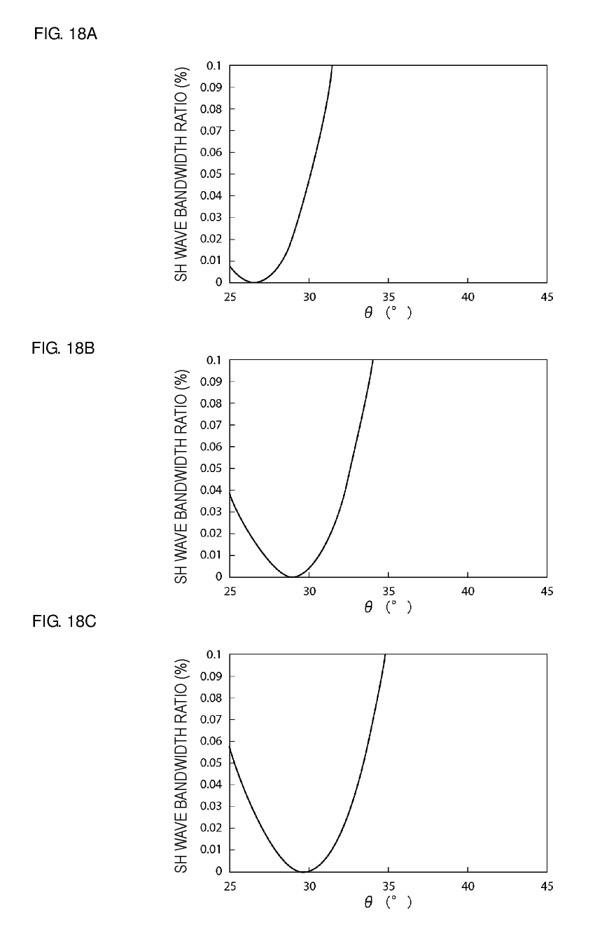

FIGS. 17A to 17C and FIGS. 18A to 18C are diagrams illustrating the relationship between θ of the Euler angles (0°, θ, 0°) and the bandwidth ratio of the shear horizontal waves when the film thickness of the Pt film is changed. In FIGS. 17A to 17C and FIGS. 18A to 18C, the film thickness of the Pt film is respectively set to about 0.015λ, about 0.025λ, about 0.035λ, about 0.055λ, about 0.065λ, and about 0.075λ in this order, for example. In addition, FIGS. 17 and 18 illustrate results that were obtained when an elastic wave resonator designed as stipulated below was provided with the structure illustrated in FIGS. 1 and 2.

Piezoelectric substrate 2 . . . LiNbO₃ substrate, Euler angles (0°, θ, 0°)

First electrode layer 3a . . . Pt film

Second electrode layer 3b . . . Al film, film thickness: about 0.10λ

IDT electrode 3 . . . duty ratio: about 0.50

Dielectric layer 6 . . . SiO₂ film, film thickness D: about 0.35λ

Elastic waves . . . principle mode: Rayleigh waves

The bandwidth ratio (%) is obtained from bandwidth ratio (%)={(anti-resonant frequency−resonant frequency)/resonant frequency}×100. The bandwidth ratio (%) is in a proportional relationship with the electromechanical coupling coefficient (K²).

It is clear from FIGS. 17A to 17C that the value of θ where the electromechanical coupling coefficient of the shear horizontal waves with the smallest value becomes larger as the film thickness of the Pt film becomes larger in the range of the film thickness of the Pt film of about 0.015λ to about 0.035λ, for example. On the other hand, it is clear from FIG. 18A that the value of θ where the electromechanical coupling coefficient of the shear horizontal waves with the smallest value is reduced to about 27° when the film thickness of the Pt film is about 0.055λ, for example. In addition, it is clear from FIG. 18B that θ is about 29° when the film thickness of the Pt film is about 0.065λ, for example. In addition, it is clear from FIG. 18C that θ is about 30° when the film thickness of the Pt film is about 0.075λ, for example.

Therefore, it is clear that it is preferable to make the film thickness of the Pt film at least larger than about 0.035λ in order to make the Euler angle θ at which the spurious of the higher-order mode is able to be sufficiently significantly reduced or prevented be equal to or less than about 32°, for example.

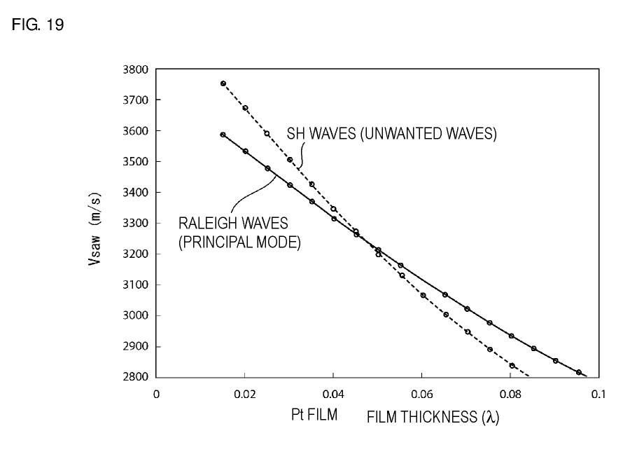

The reason why the minimum or substantially minimum value of the electromechanical coupling coefficient of the shear horizontal waves changes greatly in the range where the film thickness of the Pt film is about 0.035λ to about 0.055λ, for example, is able to be explained with respect to FIG. 19.

FIG. 19 is a diagram illustrating the relationships between the film thickness of the Pt film and the acoustic velocities of Rayleigh waves and shear horizontal waves. In the figure, a solid line represents the results for Rayleigh waves, which are used as the principle mode, and a broken line represents the results for shear horizontal waves, which are unwanted waves. FIG. 19 illustrates results that were obtained when an elastic wave resonator designed as stipulated below was provided in the structure illustrated in FIGS. 1 and 2.

Piezoelectric substrate 2 . . . LiNbO₃ substrate, Euler angles (0°, about 28°, 0°)

First electrode layer 3a . . . Pt film

Second electrode layer 3b . . . Al film, film thickness: about 0.10λ

IDT electrode 3 . . . duty ratio: about 0.60 Dielectric layer 6 . . . SiO₂ film, film thickness D: about 0.35λ

Elastic waves . . . principle mode: Rayleigh waves

It is clear from FIG. 19 that the acoustic velocity of the shear horizontal waves is greater than the acoustic velocity of the Rayleigh waves when the film thickness of the Pt film is smaller than about 0.047λ. Conversely, it is clear that the acoustic velocity of the Rayleigh waves is greater than the acoustic velocity of the shear horizontal waves when the film thickness of the Pt film is greater than or equal to about 0.047λ. From these results, it is clear that at the point where the Pt film thickness is about 0.047λ, for example, the relationship between the acoustic velocities of the shear horizontal waves and the Rayleigh waves changes and consequently, the value of θ at which the electromechanical coupling coefficient of the shear horizontal waves with a minimum or a substantial minimum value decreases. In other words, when the Pt film thickness is greater than or equal to about 0.047λ, for example, θ is able to be made less than or equal to about 32° and the electromechanical coupling coefficient of the shear horizontal waves is able to be significantly reduced.

Therefore, the film thickness of the first electrode layer 3a is preferably a thickness at which the acoustic velocity of the shear horizontal waves is lower than the acoustic velocity of the Rayleigh waves.

Specifically, in the case where a Pt film is included as the first electrode layer 3a, the film thickness of the Pt film is preferably greater than or equal to about 0.047λ, for example. In this case, the electromechanical coupling coefficient of the shear horizontal waves is able to be made small, and generation of unwanted waves in the vicinity of the passband (acoustic velocity: about 3700 m/s) is able to be significantly reduced or prevented. In addition, from the fact that the aspect ratio of the electrode becomes larger and the shape of the electrode may become problematic as the total thickness of the electrode increases, the total thickness of the electrode including Al is preferably, for example, less than or equal to about 0.25λ.

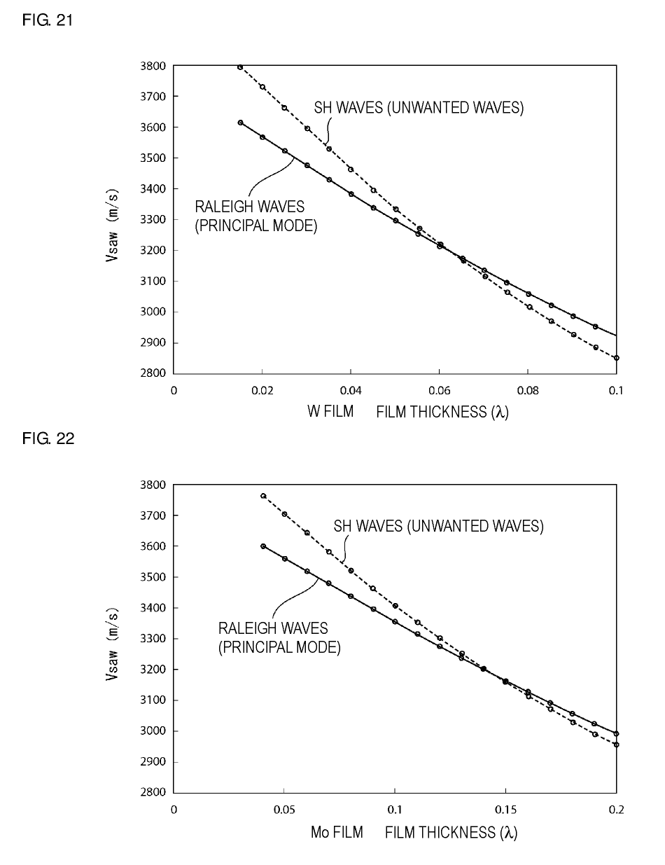

FIG. 21 is a diagram illustrating the relationships between the film thickness of a W film and the acoustic velocities of Rayleigh waves and shear horizontal waves. In the figure, a solid line represents the results for Rayleigh waves, which are used as the principle mode, and a broken line represents the results for shear horizontal waves, which are unwanted waves. FIG. 21 illustrates results obtained when an elastic wave resonator was provided with a same or similar design as that provided in the case illustrated in FIG. 19 except that a W film of a prescribed thickness was provided as the first electrode layer 3a.

It is clear from FIG. 21 that, in the case where a W film is included, the relationship between the acoustic velocity of the Rayleigh waves and the acoustic velocity of the shear horizontal waves inverts at a point where the film thickness of the W film is about 0.062λ, for example. Therefore, in the case where a W film is included, the Euler angle θ is able to be made less than or equal to about 32° and the electromechanical coupling coefficient is able to be significantly reduced when the film thickness of the W film is greater than or equal to about 0.062λ, for example.

Therefore, in the case where a W film is included as the first electrode layer 3a, the film thickness of the W film is preferably, for example, greater than or equal to about 0.062λ. In this case, the electromechanical coupling coefficient of the shear horizontal waves is able to be made small, and generation of unwanted waves in the vicinity of the passband (acoustic velocity: about 3700 m/s) is able to be significantly reduced or prevented.

FIG. 22 is a diagram illustrating the relationships between the film thickness of a Mo film and the acoustic velocities of Rayleigh waves and shear horizontal waves. In the figure, a solid line represents the results for Rayleigh waves, which are used as the principle mode, and a broken line represents the results for shear horizontal waves, which are unwanted waves. FIG. 22 illustrates results obtained when an elastic wave resonator was provided with a same or similar design as that provided in the case illustrated in FIG. 19 except that a Mo film of a prescribed thickness was provided as the first electrode layer 3a.

It is clear from FIG. 22 that, in the case where a Mo film is included, the relationship between the acoustic velocity of the Rayleigh waves and the acoustic velocity of the shear horizontal waves inverts at a point where the film thickness of the Mo film is about 0.144λ, for example.

Therefore, in the case where a Mo film is included, the Euler angle θ is able to be made less than or equal to about 32° and the electromechanical coupling coefficient is able to be significantly reduced when the film thickness of the Mo film is greater than or equal to about 0.144λ, for example.

Therefore, in the case where a Mo film is included as the first electrode layer 3a, the film thickness of the Mo film is preferably, for example, greater than or equal to about 0.144λ. In this case, the electromechanical coupling coefficient of the shear horizontal waves is able to be made small, and generation of unwanted waves in the vicinity of the passband is able to be significantly reduced or prevented.

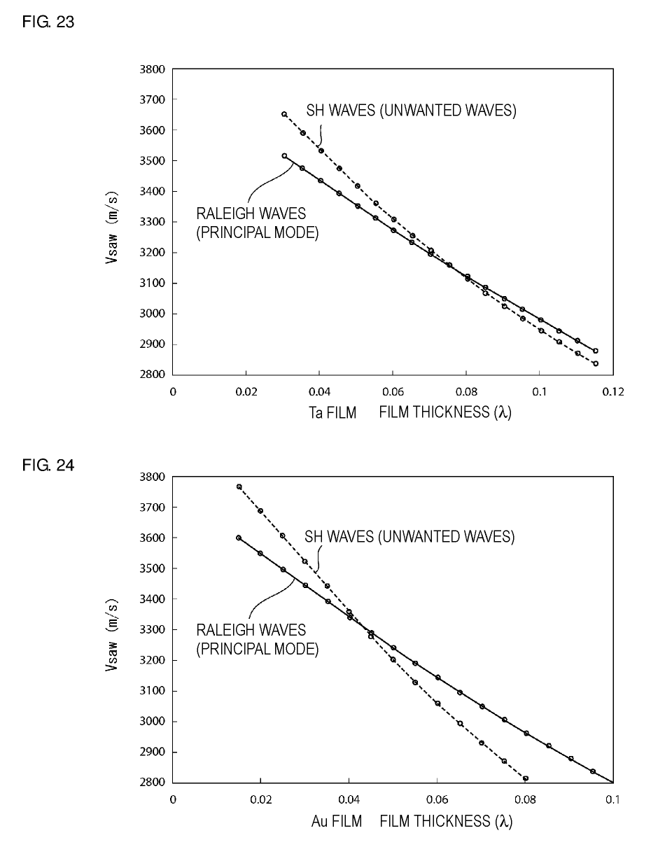

FIG. 23 is a diagram illustrating the relationships between the film thickness of a Ta film and the acoustic velocities of Rayleigh waves and shear horizontal waves. In the figure, a solid line represents the results for Rayleigh waves, which are used as the principle mode, and a broken line represents the results for shear horizontal waves, which are unwanted waves. FIG. 23 illustrates results obtained when an elastic wave resonator was provided with a same or similar design as that provided in the case illustrated in FIG. 19 except that a Ta film of a prescribed thickness was provided as the first electrode layer 3a.

It is clear from FIG. 23 that, in the case where a Ta film is included, the relationship between the acoustic velocity of the Rayleigh waves and the acoustic velocity of the shear horizontal waves inverts at a point where the film thickness of the Ta film is about 0.074λ, for example.

Therefore, in the case where a Ta film is included, the

Euler angle θ is able to be made less than or equal to about 32° and the electromechanical coupling coefficient is able to be significantly reduced when the film thickness of the Ta film is greater than or equal to about 0.074λ, for example.

Therefore, in the case where a Ta film is included as the first electrode layer 3a, the film thickness of the Ta film is preferably, for example, greater than or equal to about 0.074λ. In this case, the electromechanical coupling coefficient of the shear horizontal waves is able to be made small, and generation of unwanted waves in the vicinity of the passband is able to be significantly reduced or prevented.

FIG. 24 is a diagram illustrating the relationships between the film thickness of an Au film and the acoustic velocities of Rayleigh waves and shear horizontal waves. In the figure, a solid line represents the results for Rayleigh waves, which are used as the principle mode, and a broken line represents the results for shear horizontal waves, which are unwanted waves. FIG. 24 illustrates results obtained when an elastic wave resonator was provided with a same or similar design as that provided in the case illustrated in FIG. 19 except that an Au film of a prescribed thickness was provided as the first electrode layer 3a.

It is clear from FIG. 24 that, in the case where an Au film is included, the relationship between the acoustic velocity of the Rayleigh waves and the acoustic velocity of the shear horizontal waves inverts at a point where the film thickness of the Au film is about 0.042λ, for example.

Therefore, in the case where an Au film is included, the Euler angle θ is able to be made less than or equal to about 32° and the electromechanical coupling coefficient is able to be significantly reduced when the film thickness of the Au film is greater than or equal to about 0.042λ, for example.

Therefore, in the case where an Au film is included as the first electrode layer 3a, the film thickness of the Au film is preferably, for example, greater than or equal to about 0.042λ, for example. In this case, the electromechanical coupling coefficient of the shear horizontal waves is able to be made small, and generation of unwanted waves in the vicinity of the passband is able to be significantly reduced or prevented.

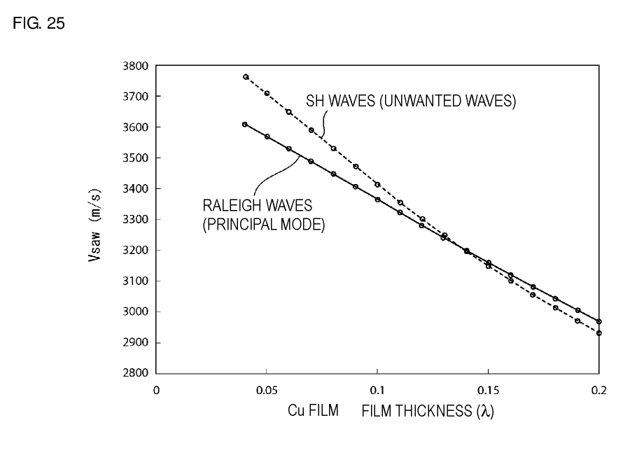

FIG. 25 is a diagram illustrating the relationships between the film thickness of a Cu film and the acoustic velocities of Rayleigh waves and shear horizontal waves. In the figure, a solid line represents the results for Rayleigh waves, which are used as the principle mode, and a broken line represents the results for shear horizontal waves, which are unwanted waves. FIG. 25 illustrates results obtained when an elastic wave resonator was provided with a same or similar design as that provided in the case illustrated in FIG. 19 except that a Cu film of a prescribed thickness was provided as the first electrode layer 3a.

It is clear from FIG. 25 that, in the case where a Cu film is included, the relationship between the acoustic velocity of the Rayleigh waves and the acoustic velocity of the shear horizontal waves inverts at a point where the film thickness of the Cu film is about 0.136λ, for example.

Therefore, in the case where a Cu film is included, the Euler angle θ is able to be made less than or equal to about 32° and the electromechanical coupling coefficient is able to be significantly reduced when the film thickness of the Cu film is greater than or equal to about 0.136λ, for example.

Therefore, in the case where a Cu film is included as the first electrode layer 3a, the film thickness of the Cu film is preferably, for example, greater than or equal to about 0.136λ. In this case, the electromechanical coupling coefficient of the shear horizontal waves is able to be made small, and generation of unwanted waves in the vicinity of the passband is able to be significantly reduced or prevented.

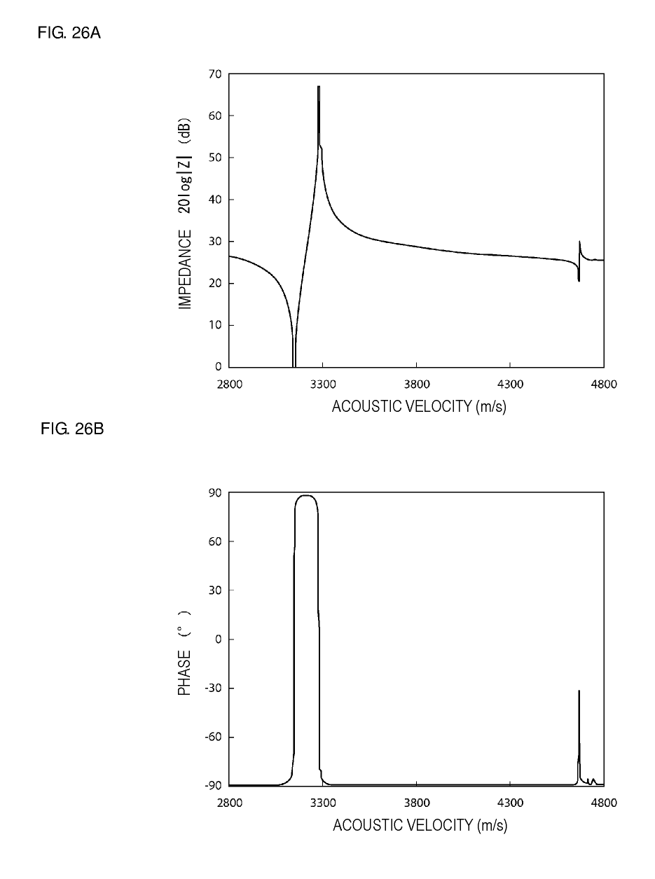

In FIGS. 26 to 28, parts (a) are diagrams illustrating the impedance characteristics and parts (b) are diagrams illustrating the phase characteristics for when the duty ratio is changed.

In addition, FIGS. 26 to 28 respectively illustrate results obtained when the duty ratio was set to about 0.50, about 0.60, and about 0.70 in this order, for example. FIGS. 26 to 28 illustrate results that were obtained when an elastic wave resonator designed as stipulated below was provided with the structure illustrated in FIGS. 1 and 2.

Piezoelectric substrate 2 . . . LiNbO₃ substrate, Euler angles (0°, about 28°, 0°)

First electrode layer 3a . . . Pt film, film thickness: about 0.06λ

Second electrode layerb . . . Al film, film thickness: about 0.10λ

Dielectric layer 6 . . . SiO₂ film, film thickness D: about 0.32λ

Elastic waves . . . principle mode: Rayleigh waves

It is clear from FIGS. 26 to 28 that spurious of the higher-order mode is more greatly reduced or prevented as the duty ratio increases.

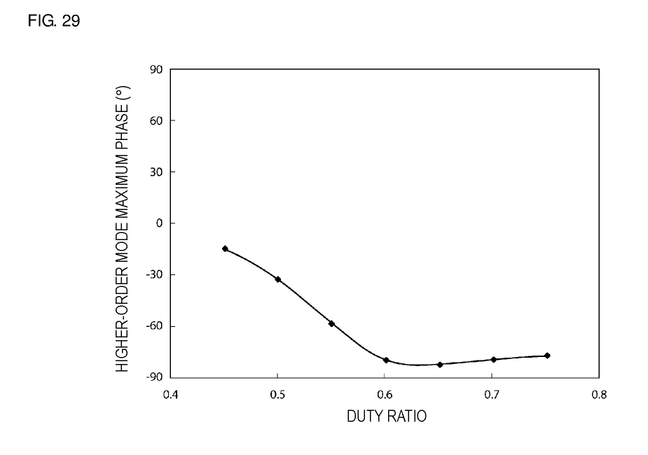

FIG. 29 is a diagram illustrating the relationship between the duty ratio of an IDT electrode and the maximum or substantially maximum phase of a higher-order mode. FIG. 29 illustrates results obtained when an elastic wave resonator with a same or similar design as that provided in the case illustrated in FIGS. 26 to 28 was provided. It is clear from FIG. 29 that the maximum phase of the higher-order mode is less than or equal to about −25° when the duty ratio is greater than or equal to about 0.48, for example. In addition, it is clear that the maximum phase of the higher-order mode is less than or equal to about −60° when the duty ratio is greater than or equal to about 0.55, for example. Therefore, the duty ratio of the IDT electrode 3 is preferably greater than or equal to about 0.48 and more preferably greater than or equal to about 0.55 from the viewpoint of further significantly reducing or preventing spurious of the higher-order mode, for example. In addition, the duty ratio is preferably, for example, less than or equal to about 0.80 from the fact that the gap between adjacent electrode fingers is small when the duty ratio is large.

Next, taking the above into account, the following elastic wave resonator was designed for the structure illustrated in FIGS. 1 and 2.

Piezoelectric substrate 2 . . . LiNbO₃ substrate, Euler angles (0°, about 28°, 0°)

First electrode layer 3a . . . Pt, film thickness: about 0.06λ

Second electrode layer 3b . . . Al, film thickness: about 0.10λ

IDT electrode 3 . . . duty ratio: about 0.50

Dielectric layer 6 . . . SiO₂, film thickness D: about 0.40λ

Elastic waves . . . principle mode: Rayleigh waves

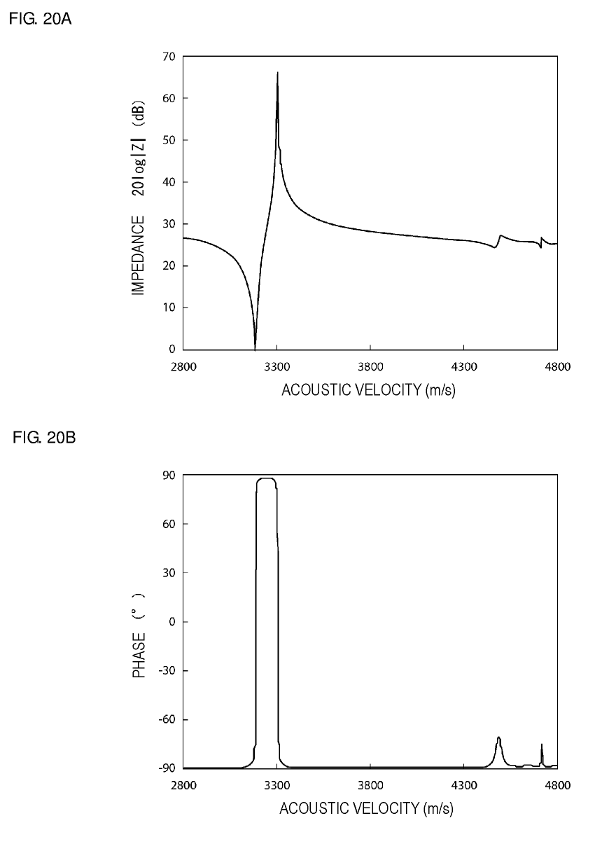

FIG. 20A is a diagram illustrating the impedance characteristic and FIG. 20B is a diagram illustrating a phase characteristic of the elastic wave resonator designed as described above.

It is clear from FIGS. 20A and 20B that higher-order mode spurious and shear horizontal wave spurious are significantly reduced or prevented in this elastic wave resonator. In addition, since the thickness of Al film is sufficiently large, this elastic wave resonator provides low loss. In addition, in this elastic wave resonator, TCF is about −20.7 ppm/° C., so TCF is also satisfactory.

As described above, it was confirmed that an elastic wave resonator is able to be manufactured that provides low loss, significant improvement of TCF, significantly reducing or preventing of higher-order mode spurious, and significantly reducing or preventing of unwanted waves in the vicinity of the passband.

Although results for Euler angles of (0°, θ, 0°) have been described in the experimental examples with respect to FIGS. 3 to 29, it is able to be confirmed that similar results are also obtained in a range of Euler angles of (about 0°±5°, θ, about 0°±10°).

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An elastic wave device comprising:
a piezoelectric substrate;
an IDT electrode that is provided on the piezoelectric substrate; and
a dielectric layer that is provided on the piezoelectric substrate and covers the IDT electrode; wherein
the IDT electrode includes a first electrode layer and a second electrode layer that is stacked on the first electrode layer, the first electrode layer including a metal or an alloy with a higher density than a metal included in the second electrode layer and a dielectric included in the dielectric layer; and
the piezoelectric substrate includes LiNbO₃, and θ of Euler angles (about 0°±5°, θ, about 0°±10°) of the piezoelectric substrate is within a range of about 8° to about 32°.

2. The elastic wave device according to claim 1, wherein θ of the Euler angles of the piezoelectric substrate is within a range of about 12° to about 26°.

3. The elastic wave device according to claim 1, wherein
Rayleigh waves are used as a principle mode of elastic waves that propagate along the piezoelectric substrate excited by the IDT electrode;
the first electrode layer includes a thickness at which an acoustic velocity of shear horizontal waves is lower than an acoustic velocity of the Rayleigh waves.

4. The elastic wave device according to claim 1, wherein the first electrode layer includes at least one selected from a group consisting of Pt, W, Mo, Ta, Au and Cu and alloys of these metals.

5. The elastic wave device according to claim 1, wherein
the first electrode layer includes Pt or an alloy including Pt as a main component; and
a thickness of the first electrode layer is greater than or equal to about 0.047λ.

6. The elastic wave device according to claim 1, wherein
the first electrode layer includes W or an alloy including W as a main component; and
a thickness of the first electrode layer is greater than or equal to about 0.062λ.

7. The elastic wave device according to claim 1, wherein
the first electrode layer includes Mo or an alloy including Mo as a main component; and
a thickness of the first electrode layer is greater than or equal to about 0.144λ.

8. The elastic wave device according to claim 1, wherein
the first electrode layer includes Ta or an alloy including Ta as a main component; and
a thickness of the first electrode layer is greater than or equal to about 0.074λ.

9. The elastic wave device according to claim 1, wherein
the first electrode layer includes Au or an alloy including Au as a main component; and
a thickness of the first electrode layer is greater than or equal to about 0.042λ.

10. The elastic wave device according to claim 1, wherein
the first electrode layer includes Cu or an alloy including Cu as a main component; and
a thickness of the first electrode layer is greater than or equal to about 0.136λ.

11. The elastic wave device according to claim 1, wherein the second electrode layer includes Al or an alloy including Al as a main component.

12. The elastic wave device according to claim 11, wherein a thickness of the second electrode layer is greater than or equal to about 0.0175λ.

13. The elastic wave device according to claim 1, wherein the dielectric layer includes at least one dielectric out of SiO₂ and SiN.

14. The elastic wave device according to claim 13, wherein the dielectric layer includes SiO₂.

15. The elastic wave device according to claim 14, wherein a film thickness of the dielectric layer is greater than or equal to about 0.30λ.

16. The elastic wave device according to claim 1, wherein a duty ratio of the IDT electrode is greater than or equal to about 0.48.

17. The elastic wave device according to claim 1, wherein a duty ratio of the IDT electrode is greater than or equal to about 0.55.

18. The elastic wave device according to claim 1, wherein
at least one reflector is provided on a same surface of the piezoelectric substrate as the IDT electrode; and
the at least one reflector is located at a side of the IDT electrode in a propagation direction of an elastic wave that propagates along the piezoelectric substrate.

19. The elastic wave device according to claim 1, wherein the elastic wave device defines a one-port elastic wave resonator.

20. The elastic wave device according to claim 1, wherein the IDT electrode includes first and second electrode fingers that extend in a direction perpendicular or substantially perpendicular to a propagation direction of an elastic wave that propagates along the piezoelectric substrate.
